(19) United States
(12) Patent Application Publication
(10) Pub. No.: US 2018/0301958 A1
(43) Pub. Date: Oct. 18, 2018

(54) SIGNAL SHIELDING METHOD, SIGNAL SHIELDING DEVICE, AND ELECTRONIC DEVICE WITH SIGNAL SHIELDING DEVICE

(71) Applicants: Fu Tai Hua Industry (Shenzhen) Co., Ltd., Shenzhen (CN); HON HAI PRECISION INDUSTRY CO., LTD., New Taipei (TW)

(72) Inventor: ZHAN-YI CHEN, Shenzhen (CN)

(21) Appl. No.: 15/688,875

(22) Filed: Aug. 29, 2017

(30) Foreign Application Priority Data
Apr. 13, 2017 (CN) 201710240281.1

(51) Int. Cl. H02K 11/22; H05K 9/00; G01R 29/08; H02K 11/01

(52) U.S. Cl. CPC H02K 11/022; H05K 9/0007; H02K 11/01; H05K 9/0073; G01R 29/08; H05K 9/0056

(57) ABSTRACT

A signal shielding device for shielding electronic components of a circuit board in an electronic device includes a shielding frame and a shielding cover. The shielding frame comprising an opening and a side wall forming the opening. The shielding cover covers the opening of the shielding frame and adheres flush to the shielding frame by a conductive adhesive.

### CROSS-REFERENCE TO RELATED APPLICATIONS

This application claims priority to Chinese Patent Application No. 201710240281.1 filed on Apr. 13, 2017, the contents of which are incorporated by reference herein.

### FIELD

The subject matter herein generally relates to electronic product field, and particularly, to a signal shielding method, a signal shielding device and an electronic device with the signal shielding device.

### BACKGROUND

Some electronic products, such as smart phone or tablet computer have circuit board or special chip to process data. However, the circuit board or the special chip will generate electromagnet radiation and electrostatic discharge when the circuit board or the special chip works. Thus, the circuit board or the special chip is easily affected by the electromagnetic interference and the radio frequency interference, which may cause fault in the electronic product. Therefore, a shielding cover is needed to guarantee the electronic product works normally.

### BRIEF DESCRIPTION OF THE DRAWINGS

Implementations of the present disclosure will now be described, by way of example only, with reference to the attached figures.

FIG. 1 is an isometric view showing an exemplary embodiment of an electronic device.

FIG. 2 is an exploded, isometric view of the electronic device of FIG. 1.

FIG. 3 is a flowchart of one embodiment of a signal shielding method.

### DETAILED DESCRIPTION

It will be appreciated that for simplicity and clarity of illustration, where appropriate, reference numerals have been repeated among the different figures to indicate corresponding or analogous elements. In addition, numerous specific details are set forth in order to provide a thorough understanding of the exemplary embodiments described herein. However, it will be understood by those of ordinary skill in the art that the exemplary embodiments described herein can be practiced without these specific details. In other instances, methods, procedures, and components have not been described in detail so as not to obscure the related relevant feature being described. The drawings are not necessarily to scale and the proportions of certain parts may be exaggerated to better illustrate details and features. The description is not to be considered as limiting the scope of the exemplary embodiments described herein.

The term “comprising” means “including, but not necessarily limited to”; it specifically indicates open-ended inclusion or membership in a so-described combination, group, series, and the like.

Exemplary embodiments of the present disclosure will be described in relation to the accompanying drawings.

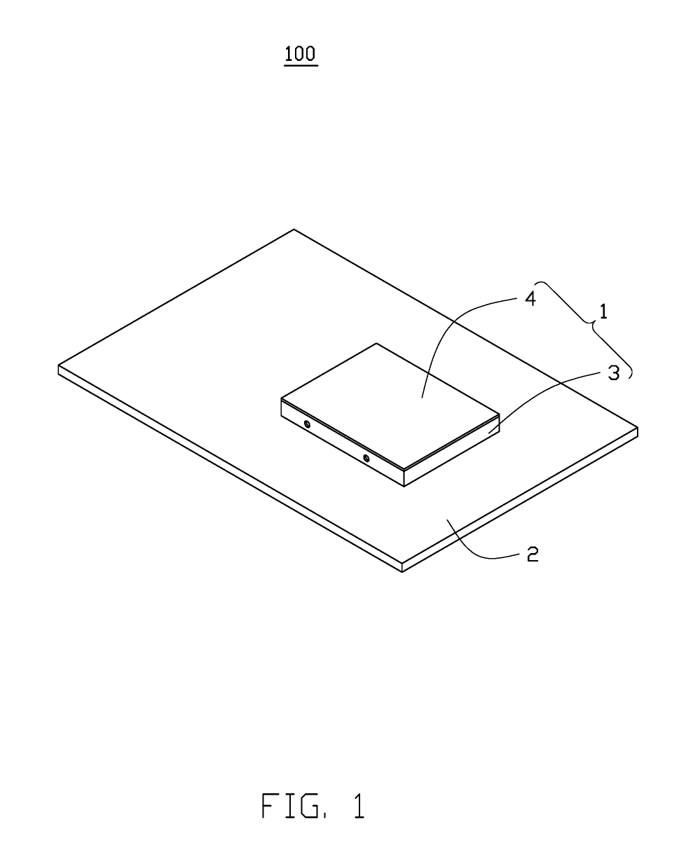

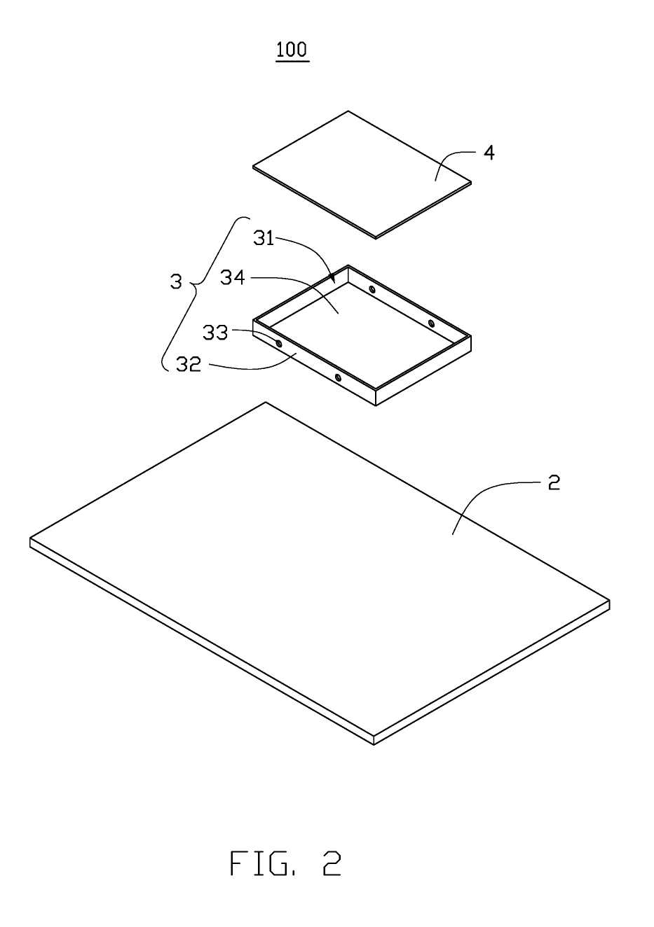

FIG. 1 illustrates an isometric view showing an exemplary embodiment of an electronic device 100. The electronic device 100 includes a signal shielding device 1 and a circuit board 2. The signal shielding device 1 includes a shielding frame 3 and a shielding cover 4. The shielding frame 3 is set on the circuit board 2. In at least one exemplary embodiment, the thickness of the shielding cover 4 is 0.5 mm. FIG. 2 illustrates an exploded, isometric view of the electronic device 100. The shielding frame 3 includes an opening 31 and a side wall 32. The side wall 32 which extends upwards forms the opening 31. The side wall 32 is set on the circuit board 2. In at least one exemplary embodiment, one end of the side wall 31 away from the opening 31 is set on the circuit board 2. In at least one exemplary embodiment, the thickness of the side wall 32 is 0.5 mm. In at least one exemplary embodiment, the opening 31 matches with the shielding cover 4. The shielding cover 4 covers the opening 31 of the shielding frame 3 and the shielding cover 4 adheres to the shielding frame 3 by a conductive adhesive.

In at least one exemplary embodiment, a receiving cavity 34 is formed between the shielding frame 3 and the shielding cover 4. The receiving cavity 34 is used to receive electronic component (not shown) of the circuit board 2. In at least one exemplary embodiment, the electronic device 100 can be smart phone, notebook computer, or tablet computer. The shielding frame 3 and the shielding cover 4 can be metal sheet having electrical conductivity. The conductive adhesive can be medium-temperature curing conductive adhesive or ultraviolet light-curable conductive adhesive.

In at least one exemplary embodiment, the shielding frame 3 is set on the circuit board 2 by soldering. The shielding frame 3 can be, but is not limited to, a cuboid structure or a cubic structure. Correspondingly, the opening 31 of the shielding frame 3 can be rectangular or square. In at least one exemplary embodiment, the side wall 32 of shielding frame 3 defines a number of heat dissipation holes 33. The heat dissipation holes 33 are for the electronic components received in the shielding frame 3 to dissipate heat.

In at least one exemplary embodiment, as the shielding cover 4 adheres to the shielding frame 3 by conductive adhesive, a seamless connection between the shielding cover 4 and the shielding frame 3 is formed. The seamless connection between the shielding cover 4 and the shielding frame 3 protects the electronic components received in the shielding frame 3, by shielding against electromagnetic interference from other electronic components of the electronic device 100. Further, as the shielding cover 4 adheres to the shielding frame 3 by conductive adhesive, the shielding cover 4 and the shielding frame 3 are easy to separate, which is beneficial in checking the electronic components received in the shielding frame 3 if they malfuntion.

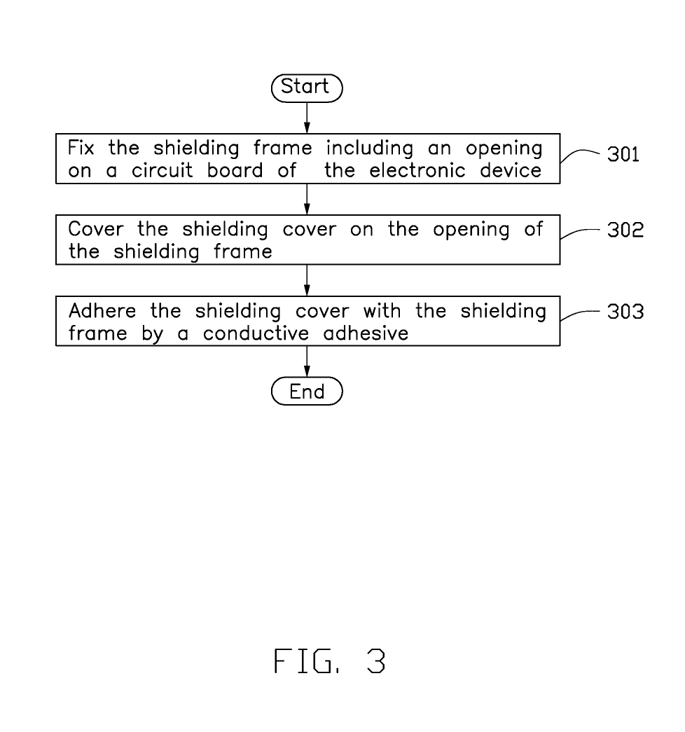

FIG. 3 illustrates a flowchart of a signal shielding method. The method is applied in an electronic device with a signal shielding device. The signal shielding device includes a shielding frame and a shielding cover. The method is provided by way of example, as there are a variety of ways to carry out the method. The method described below can be carried out using the configurations illustrated in FIGS. 1-2, for example, and various elements of these figures are referenced in explaining the example method. Each block shown in FIG. 3 represents one or more processes, methods, or subroutines carried out in the example method. Furthermore, the illustrated order of blocks is by example only and the order of the blocks can be changed. Additional blocks may be added or fewer blocks may be utilized, without departing from this disclosure. The example method can begin at block 301.

At block 301, the shielding frame including an opening is fixed to a circuit board of the electronic device. In at least one exemplary embodiment, the shielding frame is set on the circuit board by soldering.

At block 302, the shielding cover is covered on the opening of the shielding frame.

At block 303, the shielding cover is adhered with the shielding frame by a conductive adhesive. In at least one exemplary embodiment, the conductive adhesive adhesive can be medium-temperature curing conductive adhesive or ultraviolet light-curable conductive adhesive.

In at least one exemplary embodiment, set a number heat dissipation holes on side wall of the shielding frame to dissipate heat from electronic component received in the shielding frame.

The exemplary embodiments shown and described above are only examples.

Even though numerous characteristics and advantages of the present disclosure have been set forth in the foregoing description, together with details of the structure and function of the present disclosure, the disclosure is illustrative only, and changes may be made in the detail, including in matters of shape, size and arrangement of the parts within the principles of the present disclosure up to, and including, the full extent established by the broad general meaning of the terms used in the claims.

1. A signal shielding device for shielding electronic components of a circuit board, comprising:
a shielding frame set on the circuit board, the shielding frame comprising:
an opening;
a side wall extending around the opening; and
a shielding cover configured to cover the opening of the shielding frame and adhere to the shielding frame by a conductive adhesive seamlessly connecting the shielding cover with the shielding frame, wherein the seamless connection between the shielding cover and the shield frame protects the electronic components received in the shielding frame from electromagnetic interference.

2. The signal shielding device as recited in claim 1, wherein a receiving cavity is defined between the shielding frame and the shielding cover, the receiving cavity is configured to receive the electronic components of the circuit board.

3. The signal shielding device as recited in claim 1, wherein the side wall of the shielding frame defines a plurality of heat dissipation holes, wherein the plurality of the heat dissipation holes are for the electronic components received in the shielding frame to dissipate heat.

4. The signal shielding device as recited in claim 1, wherein the thickness of the shielding cover is 0.5 mm.

5. The signal shielding device as recited in claim 1, wherein the thickness of the side wall is 0.5 mm.

6. The signal shielding device as recited in claim 1, wherein the shielding frame and the shielding cover can be metal sheet having electrical conductivity.

7. The signal shielding device as recited in claim 1, wherein the conductive adhesive can be medium-temperature curing conductive adhesive or ultraviolet light-curable conductive adhesive.

8. The signal shielding device as recited in claim 1, wherein the shielding frame is set on the circuit board by soldering.

9. An electronic device comprising:
a circuit board;
a signal shielding device set on the circuit board, comprising:
a shielding frame set on the circuit board, the shielding frame comprising:
an opening;
a side wall extending around the opening; and
a shielding cover configured to cover the opening of the shielding frame and adhere to the shielding frame by a conductive adhesive seamlessly connecting the shielding cover with the shielding frame, wherein the seamless connection between the shielding cover and the shielding frame protects the electronic components received in the shielding frame from electromagnetic interference.

10. The electronic device as recited in claim 9, wherein a receiving cavity is defined between the shielding frame and the shielding cover, the receiving cavity is configured to receive electronic components of the circuit board.

11. The electronic device as recited in claim 9, wherein the side wall of the shielding frame defines a plurality of heat dissipation holes, wherein the plurality of the heat dissipation holes are for electronic components received in the shielding frame to dissipate heat.

12. The electronic device as recited in claim 9, wherein the thickness of the shielding cover is 0.5 mm.

13. The electronic device as recited in claim 9, wherein the thickness of the side wall is 0.5 mm.

14. The electronic device as recited in claim 9, wherein the shielding frame and the shielding cover can be metal sheet having electrical conductivity.

15. The electronic device as recited in claim 9, wherein the conductive adhesive can be medium-temperature curing conductive adhesive or ultraviolet light-curable conductive adhesive.

16. The electronic device as recited in claim 9, wherein the shielding frame is set on the circuit board by soldering.

17. The electronic device as recited in claim 9, wherein the electronic device can be smart phone, notebook computer, or tablet computer.

18. A signal shielding method comprising:
a shielding frame including an opening is fixed to a circuit board of an electronic device;
a shielding cover is covered on the opening of the shielding frame; and
the shielding cover is adhered with the shielding frame by a conductive adhesive seamlessly connecting the shielding cover with the shielding frame, wherein the seamless connection between the shielding cover and the shielding frame protects the electronic components received in the shielding frame from electromagnetic interference.

19. The signal shielding method as recited in claim 18, further comprising:
the shielding frame is set on the circuit board by soldering.

20. The signal shielding method as recited in claim 18, further comprising:
the shielding frame defines a plurality of heat dissipation holes.
